(19) United States
(12) Patent Application Publication
(10) Pub. No.: US 2006/0000550 A1
(43) Pub. Date: Jan. 5, 2006

(54) Apparatus for peeling release film

(75) Inventors: Kuo-Ming Yao, Miao-Li (TW); Chen-Chi Sung, Miao-Li (TW); Chia-Hsin Lin, Miao-Li (TW); Yiu-Chin Yu, Miao-Li (TW); Mao-Jui Chang, Miao-Li (TW); Hsin-Jung Yang, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/028,103

(22) Filed: Dec. 31, 2004

(30) Foreign Application Priority Data
Jun. 30, 2004 (TW) 093119342

(51) Int. Cl. B29C 63/00; H01L 21/301; H01L 21/46

(52) U.S. Cl. 156/344; 156/584; 438/464

(57) ABSTRACT

An apparatus (101) for peeling release films (142) used in the manufacturing of liquid crystal display devices includes a winding mechanism for winding a pair of tapes (130) to peel a release film off from a polarization plate (141), a release film peeling mechanism, and a detecting means (120) having a mount (122) and several detectors (121). The detectors are installed on the mount for detecting any deviation of the tape. When a deviation occurs, the relevant detector sends a signal to a control unit (150). The control unit then sends out a signal to a power supply (160) of the apparatus to turn off the apparatus. The control unit also sends out a signal to an alarm device, so as to alert relevant personnel of the occurrence of the deviation.

### BACKGROUND OF THE INVENTION

1. Field of the Invention

The present invention relates generally to apparatuses for manufacturing liquid crystal display devices, and more particularly to an apparatus for peeling release films off from polarization plates.

2. Description of the Prior Art

Manufacturing liquid crystal display devices comprises many processing steps. Among them, there is a process of gluing a polarization film onto a liquid crystal display panel (or liquid crystal cell). For conveniently gluing the polarization film onto the liquid crystal display element, a polarization plate comprising an adhesive polarization film and a release film is provided.

As shown in FIG. 5, a polarization plate 40 comprises an adhesive polarization film 41 and a release film 42. The adhesive polarization film 41 comprises an adhesive surface 43 contacting the release film 42, for gluing the polarization film 41 onto the liquid crystal display element.

In order to peel the release film 42 off from the polarization plate 40 in an automated manufacturing process, a release film peeling apparatus used in a polarization film gluing apparatus has been developed. Referring to FIG. 6 and FIG. 7, a top elevation view and a side elevation view of a conventional release film peeling apparatus 1 are shown. The release film peeling apparatus 1 comprises a first roller 31, a second roller 32, a motion driver 10, a rod 11, a guiding track 12, and two tapes 30a and 30b.

As shown in FIG. 7, the first roller 31 rotates in a counterclockwise direction, and the rod 11 slides over the polarization plate 40 such that the tapes 30 are adhered onto the release film 42 of the polarization plate 40. The second roller 32 then rotates in a clockwise direction, and collects the tapes 30 such that they peel the release film 42 off from the polarization film 41. The motion driver 10 drives the rod 11 to move back and forth along the guiding track 12, as indicated by the double-headed arrows. In order to peel the release film 42 off from the polarization plate 40, the rod 11 first guides the tapes 30 from the right-hand side of the polarization plate 40 to the left-hand side of the polarization plate 40, thereby applying the tapes 30 on the polarization plate 40. Then, the rod 11 guides the tapes from the left-hand side of the polarization plate 40 to the right-hand side of the polarization plate 40. Since the adhesion of the tapes 30 on the release film 42 is stronger than that of the release film 42 on the polarization film 41, the release film 42 is consequently peeled off from the polarization film 41.

However, when the rod 11 guides the tapes 30 to peel off the release film 42, the tapes 30 may deviate from their normal working positions because of asymmetrical movement of other structures of the release film peeling apparatus 1 or because of external interference. When such deviation occurs, the process of peeling the release film 42 may fail, thereby disrupting the entire manufacturing process. Therefore, a manufacturing means that can overcome this problem is needed.

### SUMMARY OF THE INVENTION

In light of the above, one objective of the present invention is to provide a release film peeling apparatus that can detect deviation of tapes thereof so as to prevent failure in the ongoing process of peeling off of release films.

In order to achieve the above and other objectives, an apparatus for peeling a release film off from a polarization film comprises: a winding mechanism for winding a tape that adheringly peels the release film off from the polarization film; a release film peeling mechanism comprising a guiding track and a peeling initiator, wherein the peeling initiator guides the tape in accordance with the winding mechanism and moves along the guiding track for peeling off the release film; and a detecting means comprising a mount and at least one detector, wherein the detector is installed on the mount for detecting deviation of the tape.

The detector of the present invention is preferably an optical detector, which comprises a light beam emitter and a light beam sensor. The light beam emitter emits a light beam aimed adjacent one side of the tape. If the tape deviates from its normal working position to the position aimed at by the detector, the light beam emitted from the light beam emitter is reflected by the tape, the detector detects the reflected light beam as a signal indicating a deviation of the tape, and a signal is sent to a control unit from the detector. The control unit then sends out a signal to a power supply of the apparatus to turn off the apparatus, and also sends out an alarm signal to alert relevant personnel of the occurrence of the deviation.

Other objects, advantages, and novel features of the present invention will become more apparent from the following detailed description when taken in conjunction with the accompanying drawings.

### BRIEF DESCRIPTION OF THE DRAWINGS

FIG. 1 illustrates a top elevation of a release film peeling apparatus in accordance with a first embodiment of the present invention.

FIG. 2 illustrates a side elevation of the release film peeling apparatus of FIG. 1.

FIG. 3 schematically illustrates an enlarged, bottom elevation of a detector of the release film peeling apparatus of FIG. 1.

FIG. 4 schematically illustrates an enhanced release film peeling apparatus in accordance with a second embodiment of the present invention.

FIG. 5 illustrates a side elevation of a conventional polarization plate, showing a release film thereof partly peeled off from a polarization film thereof.

FIG. 6 illustrates a top elevation of a conventional release film peeling apparatus.

FIG. 7 illustrates a side elevation of the release film peeling apparatus of FIG. 6.

### DETAILED DESCRIPTION OF THE PRESENT INVENTION

Hereinafter, the present invention is described in detail with reference to the accompanying drawings, wherein like reference numerals represent like elements.

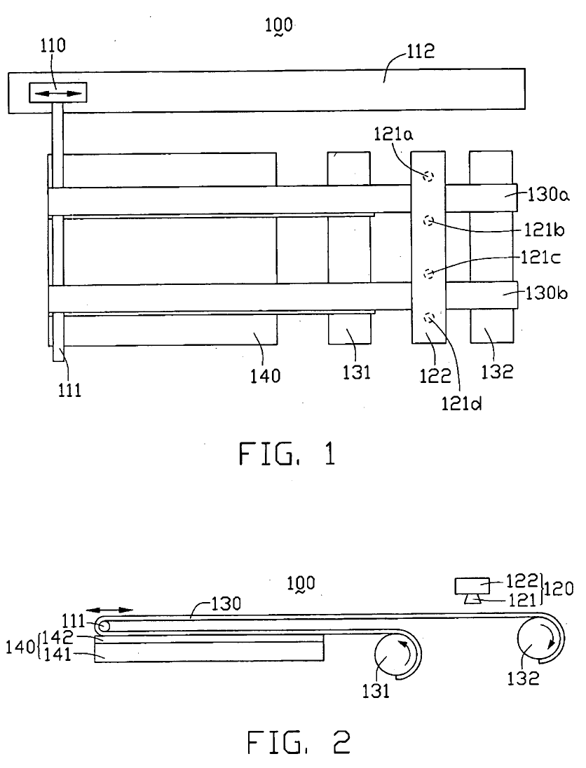

Referring to FIG. 1 and FIG. 2, a top elevation view and a side elevation view of a release film peeling apparatus 100 according to the first embodiment of the invention are shown. The release film peeling apparatus 100 comprises a first roller 131, a second roller 132, a motion driver 110, a rod 111, a guiding track 112, a detecting means 120, and two tapes 130. The two tapes 130 are a first tape 130a and a second tape 130b. The tapes 130 adhere on a release film 142 of a polarization plate 140. A strength of the adhesion is greater than that of an adhesion of the release film 142 on a polarization film 141 of the polarization plate 140.

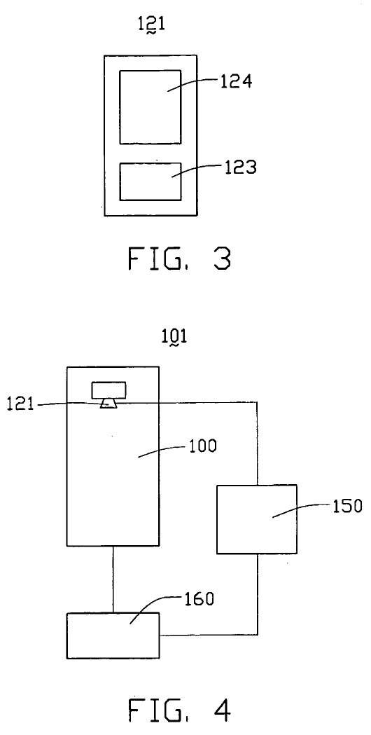

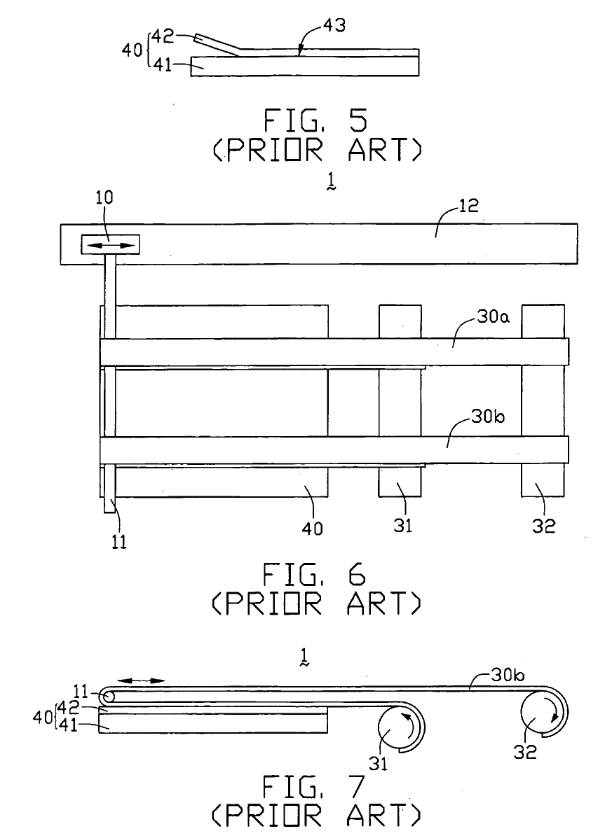

The detecting means 120 comprises a mount 122, and a plurality of detectors 121 installed on the mount 122. In the first embodiment, four detectors 121a, 121b, 121c and 121d are provided for detecting any deviations of the tapes 130. In embodiments, even one detector 121 only may be sufficient for achieving the function of detecting any deviations of the tapes 130. The detectors 121 are optical detectors. Alternatively, the detectors 121 can be any of various other types of detectors. As shown in FIG. 3, each detector 121 comprises a light beam emitter 123 and a light beam sensor 124. The light beam emitter 124 emits either a visible light beam or an infrared light beam, depending on the particular requirements of a user. The light beam sensor 124 detects the corresponding visible light beam or infrared light beam.

In assembly and preparation for use of the release film peeling apparatus 100, the motion driver 110 is attached on an end of the guiding track 112, and the rod 111 is slidably connected to the guiding track 112. The first roller 131 and the second roller 132 are rotatably fixed to a working station (not shown), and are substantially parallel to each other and kept apart a certain minimum distance. Opposite ends of each of the tapes 130a, 130b, are wound around the first roller 131 and the second roller 132 respectively, such that middle portions of the tapes 130a, 130b can be freely drawn out by the rod 111. The detecting means 120 is disposed above the tapes 130a, 130b, with the four detectors 121a, 121b, 121c and 121d corresponding to peripheries of the two tapes 130a, 130b.

In operation, the first roller 131 rotates in a counterclockwise direction, and the rod 111 slides over the polarization plate 140 so that the tapes 130 are adhered on the release film 142 of the polarization plate 140. The second roller 132 then rotates in a clockwise direction, and collects the tapes 130 such that they peel the release film 142 off from the polarization film 141. In this process, the first roller 131 and the second roller 132 rotate in opposite directions, and cooperate with the rod 111 to unwind and wind the tapes 130 such that the tapes 130 are maintained at a predetermined tension. The predetermined tension is less than a tension that may break the tapes 130. Further, the predetermined tension is greater than a tension that may allow first portions of the tapes 130 (between the rod 111 and the first roller 131) to contact respective second portions of the tapes 130 (between the rod 111 and the second roller 132). In the first embodiment, the first roller 131 and the second roller 132 winding the first tape 130a and the second tape 130b form a winding mechanism.

The motion driver 110 drives the rod 111 to move back and forth along the guiding track 112, as indicated by the double-headed arrows. In order to peel the release film 142 off from the polarization film 141, the rod 111 first guides the tapes 130 from the right-hand side of the polarization plate 140 to the left-hand side of the polarization plate 40, thereby applying the tapes 130 on the release film 142. Then, the rod 111 guides the tapes 130 from the left-hand side of the polarization plate 140 to the right-hand side of the polarization plate 140. Since the adhesion of the tapes 130 on the release film 142 is stronger than that of the release film 142 on the polarization film 141, the release film 142 is consequently peeled off from the polarization film 141. Therefore in the first embodiment, the motion driver 110, the rod 111 and the guiding track 112 can be considered to form a release film peeling mechanism, wherein the motion driver 110 and the rod 111 form a peeling initiator.

The first detector 121a emits a light beam aimed adjacent one side of the first tape 130a, while the second detector 121b emits a light beam aimed adjacent the other side of the first tape 130a. If the first tape 130a deviates from its normal working position to the position aimed at by the first detector 121a, the light beam emitted from the light beam emitter 123 of the first detector 121a is reflected by the first tape 130a, and the first detector 121a detects the reflected light beam as a signal indicating a deviation of the first tape 130a. If the first tape 130a deviates from its normal working position to the position aimed at by the second detector 121b, the light beam emitted from the light beam emitter 123 of the second detector 121b is reflected by the first tape 130a, and the second detector 121b detects the reflected light beam as a signal indicating a deviation of the first tape 130a. Likewise, the third detector 121c emits a light beam aimed adjacent one side of the second tape 130b, while the fourth detector 121d emits a light beam aimed adjacent the other side of the second tape 130b. If the second tape 130b deviates from its normal working position to the position aimed at by the third detector 121c, the light beam emitted from the light beam emitter 123 of the third detector 121c is reflected by the second tape 130b, and the third detector 121c detects the reflected light beam as a signal indicating a deviation of the second tape 130b. If the second tape 130b deviates from its normal working position to the position aimed at by the fourth detector 121d, the light beam emitted from the light beam emitter 123 of the fourth detector 121d is reflected by the second tape 130b, and the fourth detector 121b detects the reflected light beam as a signal indicating a deviation of the second tape 130b.

Although two tapes 130 are used in the release film peeling apparatus 100 of the first embodiment, in certain applications only one tape 130 may be sufficient for achieving the result of peeling off of the release film 142. The above-described rotation directions of the first roller 131 and the second roller 132 are for illustrative purposes only, and no particular limitation is intended to apply to the rotation directions.

Referring to FIG. 4, an enhanced release film peeling apparatus 101 according to the second embodiment of the invention is schematically illustrated. The enhanced release film peeling apparatus 101 comprises the release film peeling apparatus 100, a control unit 150, and a power supply 160.

In operation of the release film peeling apparatus 101, once any deviation of the tapes 130 is detected by the corresponding light beam sensor 124, the corresponding detector 121 sends out a deviation signal to the control unit 150. The control unit 150 then processes the received signal and sends out a switching signal to the power supply 160, which switches off the driving power to the release film peeling apparatus 100. The control unit 150 also sends out a signal to an alarm device such as a loudspeaker (not shown), so as to alert relevant personnel of the occurrence of the tape deviation.

In summary, with the utilization of the detecting means 120 in the release film peeling apparatus 100, any abnormal deviation of the tapes 130 can be timely detected. Further, with the aid of the control unit 150 in the enhanced release film peeling apparatus 101, the deviation can be timely corrected. As a result, the ongoing process of peeling off of successive release films 142 can be carried on with maximum efficiency and at reduced cost.

Although the present invention has been described in detail in terms of the above embodiments, other embodiments may be practiced. A person having ordinary skill in the art may make modifications and/or alterations that are within the scope of the present invention or equivalent to the present invention. Therefore, the subject matter sought to be patented is that which is defined in the following claims and allowable equivalents thereof.

1. An apparatus for peeling a release film off from a polarization film, comprising:
a winding mechanism for winding a tape that adheringly peels the release film off from the polarization film;
a release film peeling mechanism comprising a guiding track and a peeling initiator, wherein said peeling initiator guides the tape in accordance with said winding mechanism, and moves along said guiding track to peel the release film off from the polarization film; and
a detecting means comprising a mount and at least one detector, wherein the detector is installed on said mount for detecting deviation of the tape, and the detector comprises an emitter for emitting infrared light and a sensor for detecting reflected infrared light.

2. The apparatus as recited in claim 1, wherein said winding mechanism comprises a first roller and a second roller.

3. The apparatus as recited in claim 2, wherein said first roller rotates in one direction and said second roller rotates in a direction opposite to that of said first roller, for maintaining the tape at a predetermined tension.

4. The apparatus as recited in claim 1, wherein said peeling initiator comprises a rod and a motion driver.

5. The apparatus as recited in claim 4, wherein said rod applies the tape on the release film of the polarization plate, and facilitates peeling of the release film off from the polarization film.

6. The apparatus as recited in claim 4, wherein said motion driver moves said rod along said guiding track.

7-8. (canceled)

9. The apparatus as recited in claim 1, further comprising a power supply.

10. The apparatus as recited in claim 9, further comprising a control unit electrically coupled to said power supply, wherein when the detecting means detects a deviation of the tape, the detecting means sends a signal to said control unit, and said control unit sends a signal to said power supply for turning off power provided to the apparatus.

11. A method for peeling a release film off from a polarization film, comprising:
providing a winding mechanism for winding a tape that adheringly peels the release film off from the polarization film;
providing a release film peeling mechanism comprising a guiding track and a peeling initiator, wherein said peeling initiator guides the tape in accordance with said winding mechanism, and moves along said guiding track to peel the release film off from the polarization film; and
providing a detecting means comprising a mount and at least one detector, wherein the detector is installed on said mount for detecting deviation of the tape, and the detector comprises an emitter for emitting infrared light and a sensor for detecting reflected infrared light.
